(19) United States
(12) Patent Application Publication
(10) Pub. No.: US 2016/0225921 A1
(43) Pub. Date: Aug. 4, 2016

(54) METHOD FOR PRODUCING A CONTACT STRUCTURE OF A PHOTOVOLTAIC CELL AND PHOTOVOLTAIC CELL

(71) Applicant: ION BEAM SERVICES, Peynier (FR)

(72) Inventor: Tim BOESCKE, Erfurt (DE)

(73) Assignee: ION BEAM SERVICES, Peynier (FR)

(21) Appl. No.: 15/025,059

(22) PCT Filed: Sep. 26, 2014
(86) PCT No.: PCT/EP2014/070612

§ 371 Date: Mar. 25, 2016

(30) Foreign Application Priority Data
Sep. 27, 2013 (DE) 10 2013 219 599.0

(51) Int. Cl. H01L 31/02; H01L 31/0224; H01L 31/18

(52) U.S. Cl. CPC H01L 31/02008; H01L 31/18; H01L 31/022441

(57) ABSTRACT

The invention relates to a method (800) for producing a contact structure (104) of a photovoltaic cell (100), wherein the method (800) comprises a step (802) of providing, a step (804) of doping, and a step (806) of contacting. In step (802) of providing, a wafer (102) for the photovoltaic cell (100) is provided. In step (804) of doping, a surface portion of at least one side of the wafer (102) is doped with a doping material in order to obtain a doped region (106), wherein the doped region (106) is formed as doped tracks (106) and the tracks (106) are separated by intermediate spaces (110). In step (806) of contacting, the doped region (106) is contacted in order to produce the contact structure (104), wherein a conductor material (108) is applied to the tracks (106) in such a way that the tracks (106) protrude beyond the conductor material (108) on both sides.

### STATE OF THE ART

The present invention concerns a method for producing a contact structure of a photovoltaic cell as well as a photovoltaic cell.

A semiconductor material of a photovoltaic cell is doped with at least two different doping materials to create a p-n transition in the semiconductor material. Electric charges can be separated at the transition level so as to obtain an electric potential by using incident light. The electric potential can be tapped from the semiconductor material via conductor tracks.

DE 10 2009 034 594 A1 describes a method for producing a crystalline silicon solar cell with full-surface, alloyed rear side metallisation.

### DISCLOSURE OF THE INVENTION

In this context, the present invention relates to a method for producing a contact structure of a photovoltaic cell as well as a photovoltaic cell according to the main claims. Advantageous embodiments can be deduced from the respective subclaims and the following description.

There may be several objectives when doping the semiconductor material of a photovoltaic cell and when contacting the doped semiconductor material. By way of example, a high doping enables to obtain a lower transition resistance between the semiconductor material and a contact material. The high doping also generates internal losses in the semiconductor material which can be decreased when the doping is reduced. The lower doping generates conversely a high transition resistance between the semiconductor material and the contact material. A high doping enables additionally to increase an electrical conductivity inside the doped region.

To combine smaller internal losses with reduced transition losses, regions around the conductor tracks of the photovoltaic cell can be highly-doped, while intermediate spaces are little or not doped between the highly-doped regions.

This enables to obtain a high total efficiency of the photovoltaic cell.

The invention provides a method for producing a contact structure of a photovoltaic cell, whereas the method comprises the following steps:

providing a wafer for the photovoltaic cell;

doping a surface portion of at least one side of the wafer with a doping material, to obtain a doped region, whereas the doped region is formed as doped tracks and the tracks are separated by intermediate spaces; and contacting the doped region to produce the contact structure, whereas a conductor material is applied to the tracks in such a way that the tracks protrude beyond the conductor material on both sides.

By photovoltaic cell can be meant a solar cell. By wafer can be meant a disc of semiconductor material. The semiconductor material can already be pre-doped with foreign atoms. The semiconductor material can also be present in pure form. The doping may consist in injecting into the semiconductor material atoms or ions of another species as the semiconductor material. A track can be a strip. The tracks can be contiguous at contact points. During contacting, a small strip of metal material can be applied on the doped tracks. The metal material can be silver-based by way of example. The conductor material can be printed on the doped tracks.

A surface portion can be doped between 20 percent and 90 percent, in particular between 40 percent and 60 percent, of at least one side of the wafer. The higher the doped surface portion, the larger the internal losses can be, such as for instance recombination losses in the photovoltaic cell. To do so, the transmission losses can be reduced inside the photovoltaic cell.

During the doping step, the rear side can be doped to generate the contact structure on the rear side of the photovoltaic cell. More advantageously, the contact structure can be introduced on the rear side of the photovoltaic cell.

The doped region can be in the form of at least one main track with a plurality of side tracks. The side tracks can be finger-shaped and arranged transversally to the main track. The main track and the auxiliary tracks with conductor tracks arranged thereon can be designated as a finger grid. The auxiliary tracks can have a predetermined length and cannot have additional connection to other doped regions outside the main track.

An additional doping material can be inserted to obtain an additional doped region. The additional doping material can be different from the doping material. The additional doped region can be formed as additional doped tracks. The additional tracks can be separated from the tracks by intermediate spaces. The additional doping material can form a p-n transition between the doped region and the additional doped region to separate electric charges. Differently doped regions, arranged on one side close to one another can generate a light incidence side of the photovoltaic cell with any shadowing structures which enables to increase the efficiency of the photovoltaic cell.

The tracks can be doped with a concentration of doping agent so that the specific resistance in the doped region, also called layer resistance or surface resistance or specific surface resistance, between 5 Ω/square and 150 Ω/square, in particular 20Ω/square and 60 Ω/square. Adjusting the specific resistance can enable to find a balance between the internal losses and the transmission losses. A layer resistance or surface resistance describes the electric resistance of a resistance layer when said resistance layer is traversed by a current parallel to an elongation of the resistance layer. The resistance layer is then traversed mostly vertically to the thickness of the resistance layer. The surface resistance has the unit Ω (Ohm) and can be measured with a four-point method well-known to those skilled in the art or four-point measurement or four-tip measurement. Alternately or additionally, the surface resistance can also be measured with the Van-der-Pauw measuring method.

The intermediate spaces can be doped with a lower concentration of the doping material than the tracks. A small concentration of the doping material in the intermediate spaces can minimise transmission losses in the semiconductor material while internal losses in the semiconductor material remain on a very low level. Thanks to different doping, the semiconductor material is quite conductive where there is a high current density. The recombination rate is small where the current density is not very high.

The intermediate spaces can be doped with a concentration of doping agent to obtain a specific resistance or a layer resistance between 80 Ω/square and 500 Ω/square in the intermediate spaces. Adjusting the specific resistance can enable to find a balance between the internal losses and the transmission losses.

The doping material can be introduced in a first pass in the region of the tracks and of the intermediate spaces, to obtain the concentration of the doping material of the intermediate spaces. The doping material can be introduced in a second pass in the region of the tracks to obtain the concentration of the doping material in the doped region. Two passes following each other can simplify and accelerate the doping process. This enables to do away with expensive equipment for doping with various concentrations of doping agent.

A width of the tracks and alternately or additionally a width of the intermediate spaces can be determined by adhering to a processing requirement. The internal losses and the transmission losses can be stored in relation to the width of the tracks and/or the width of the intermediate spaces and/or of the concentration of doping agent in the processing requirement. The processing requirement enables to determine minimum losses and to design the tracks accordingly.

An ion implantation process can be used during the doping step. The implantation of ions can be used particularly advantageously since the doping process can be targeted with accuracy.

According to an embodiment, the doped regions can be formed with phosphorus and applied on the rear side of a photovoltaic cell with n-type basis and boron-doped emitter. Thus, the doped region and the intermediate spaces can be formed with phosphorus and applied accordingly on the rear side of a photovoltaic cell with n-type basis and boron-doped emitter.

Moreover, a photovoltaic cell is presented with a wafer which has at least on one side a contact structure consisting of doped tracks and an applied conductor material whereas the tracks protrude beyond the conductor material on both sides and the tracks are separated by intermediate spaces.

Advantageously, a computer programme product with a programme code which can be stored on a machine-readable medium such as a semiconductor storage medium, a hard drive or an optical storage medium and can be used for carrying out the method according to one of the embodiments described above, when the programme product is performed on a computer or a device.

The invention will be better illustrated below with reference to the accompanying drawings by way of example. The figures are as follows:

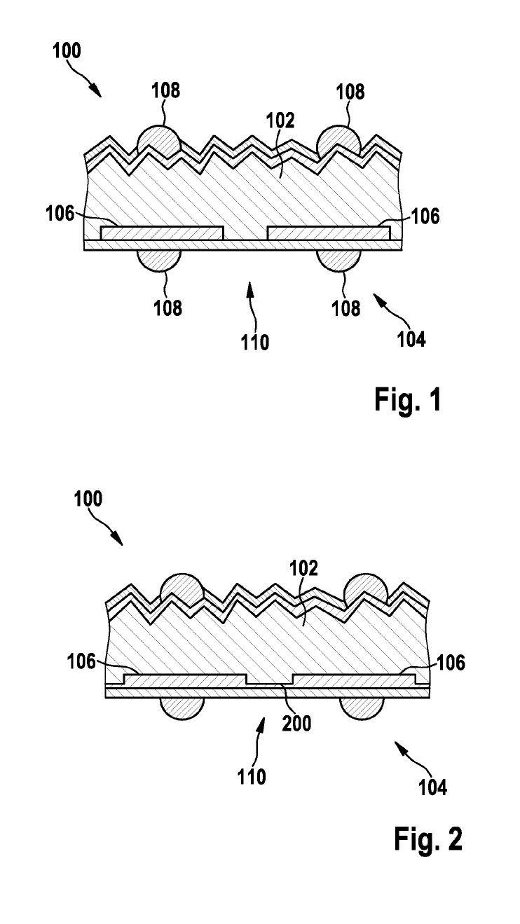

FIG. 1 shows a representation of a photovoltaic cell according to an exemplary embodiment of the present invention;

FIG. 2 shows a representation of a photovoltaic cell according to a further exemplary embodiment of the present invention;

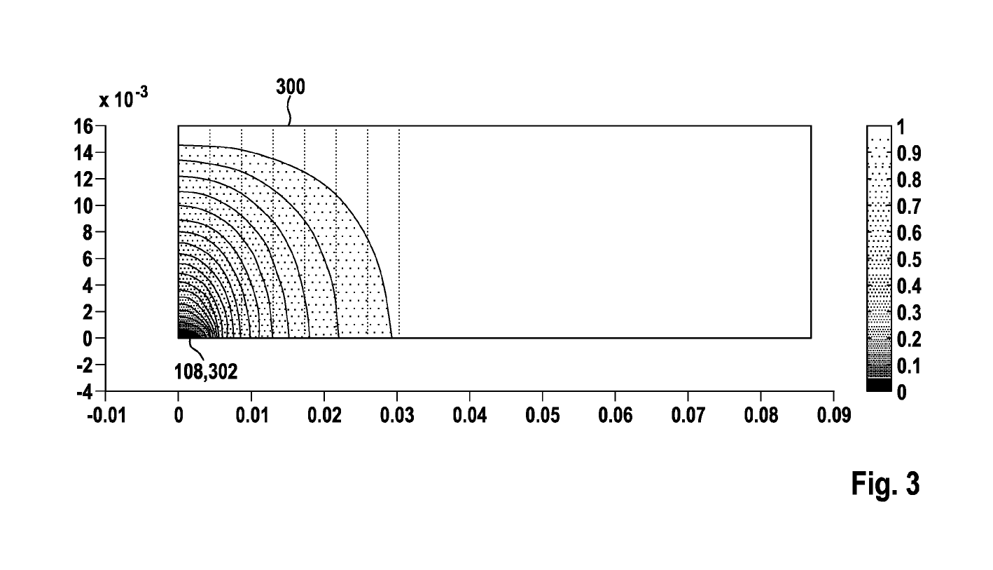

FIG. 3 shows a potential and current density distribution inside a solar cell segment with an ideally doped contact structure;

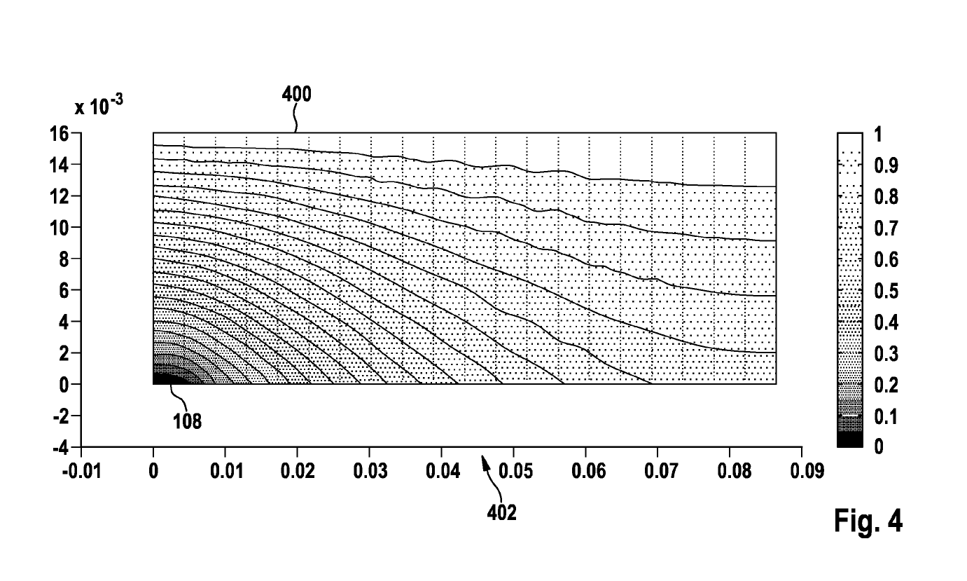

FIG. 4 shows a potential and current density distribution inside a solar cell segment with an extensively doped contact structure;

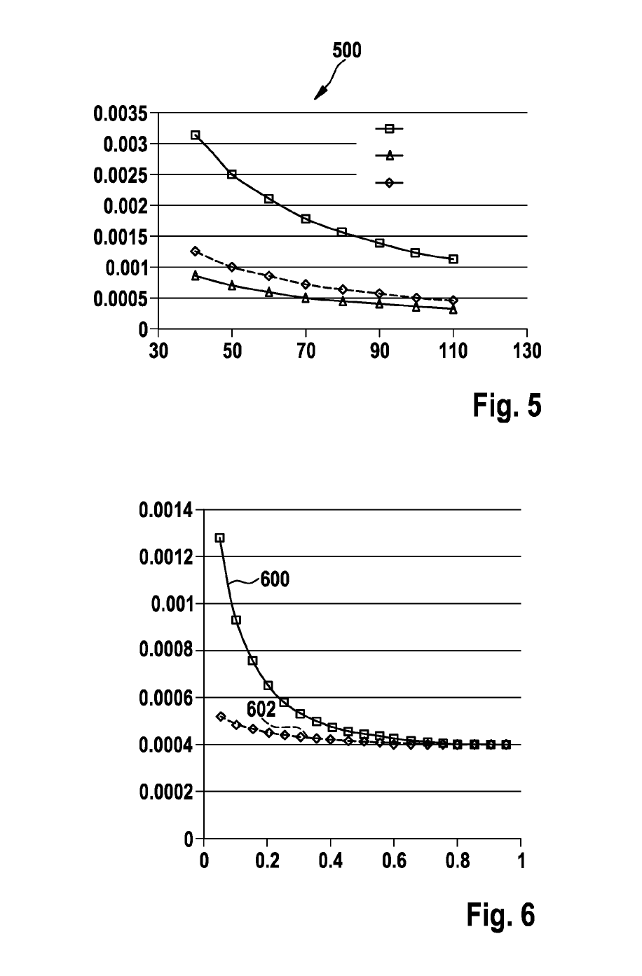

FIG. 5 shows a representation of a relation between an internal series resistance of several solar cell types and a finger quantity of a contact structure of the solar cells;

FIG. 6 shows a representation of a relation between an internal series resistance and a doped surface portion of a contact structure according to an exemplary embodiment of the present invention;

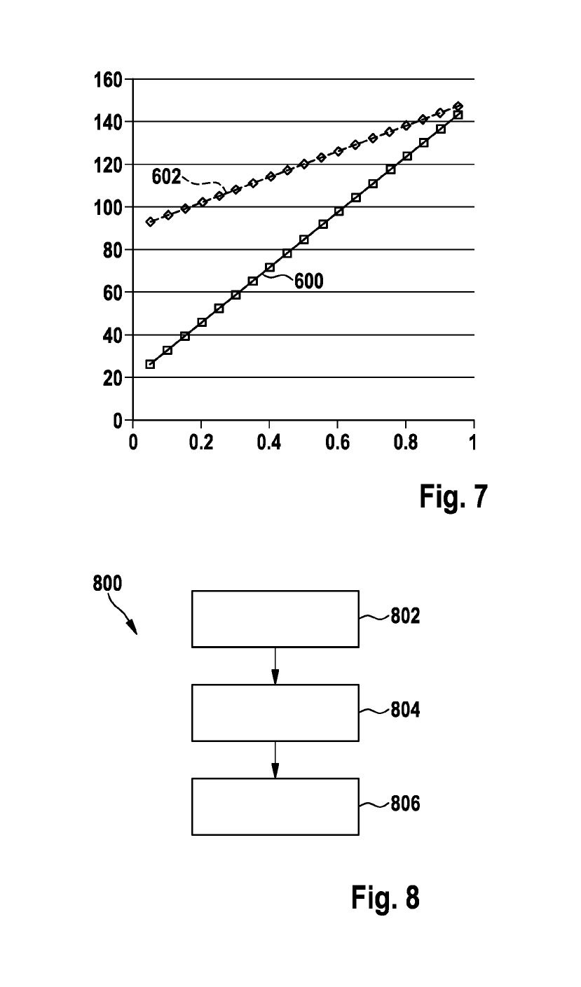

FIG. 7 shows a representation of a relation between a recombination rate and a doped surface portion of a contact structure according to an exemplary embodiment of the present invention; and

FIG. 8 shows a flow chart of a method for producing a contact structure of a photovoltaic cell according to an exemplary embodiment of the present invention.

In the following description of more appropriate examples of embodiment of the present invention, the same or similar reference signs are used for the elements with similar functions and represented in the various figures which dispenses with repeating the description of said elements.

FIG. 1 shows a representation of a photovoltaic cell 100 according to an exemplary embodiment of the present invention. The photovoltaic cell 100 includes a wafer 102 of a semiconductor material. The photovoltaic cell 100 is contacted on both sides. To do so, a contact structure 104 is provided on a rear side of the wafer 102 in this exemplary embodiment. The contact structure 104 is composed of doped tracks 106 and of an applied conductor material 108. The conductor material 108 is formed as conductor tracks. The conductor material 108 is a metal-based material. In particular, the conductor material 108 is silver or a silver-based alloy. The tracks 106 protrude beyond the conductor material 108 on both sides. The tracks 106 are separated by intermediate spaces 110. The tracks 106 cover a surface portion of the rear side of the wafer 102, a surface portion designed for minimum losses and maximum efficiency. The wafer 102 is doped on the front side of the photovoltaic cell 100 on its whole surface. The conductor tracks made of the conductor material 108 are arranged opposite to the conductor tracks of the contact structure 104. The wafer 102 is quenched and tempered between the conductor tracks on the front side so as to minimise reflection losses.

In a non-illustrated exemplary embodiment, the photovoltaic cell 100 on the front side has a contact structure according to the present application. To do so, the doped tracks are doped on the front side with another doping material than the tracks 106 on the rear side. The various doped regions act as basis and emitter of the photovoltaic cell 100.

In a non-illustrated exemplary embodiment, the photovoltaic cell 100 has two different contact structures on the rear side. In addition to the illustrated contact structure 104, the photovoltaic cell 100 has a further contact structure composed of additional tracks and conductor material 108. The additional tracks are also separated from the tracks 106 by intermediate spaces 110. The additional tracks are doped with another doping material than the tracks 106. Thus, the emitter and the basis of the photovoltaic cell 100 are arranged close to one another on the rear side of the photovoltaic cell 100.

The front side of the photovoltaic cell 100 is not contacted in this example of embodiment which causes minimum shading losses.

In other words, a cross-section of a solar cell 100 is represented with partially doped BSF (Back Surface Field) according to this application.

FIG. 2 shows a representation of a photovoltaic cell 100 according to a further exemplary embodiment of the present invention. The photovoltaic cell 100 corresponds substantially to the photovoltaic cell in FIG. 1. In addition to the photovoltaic cell represented in FIG. 1, the photovoltaic cell 100 has in the intermediate spaces 110 a small doping 200 with the same doping material as in the doped tracks 106. The small doping 200 results in increased electrical conductivity of the rear side of the photovoltaic cell 100.

In an exemplary embodiment, the whole rear side is doped with a small doping quantity 200 for producing the contact structure 104. The tracks 106 are post-doped to obtain the high level of doping which is required for reduced transition resistance between the tracks 106 and the conductor material.

In this exemplary embodiment, the tracks 106 and the small doping 200 are applied independently from one another into the wafer 102, for producing the contact structure 104. In particular, ion implantation enables to control and locate the doping intensity correctly in space.

The application shown in FIGS. 1 and 2 presents a solar cell 100 contacted on both sides with a partially doped rear side. A structure 104 is described for a solar cell 100 contacted on both sides with increased efficiency.

For increased efficiency of industry standard solar cells 100, the electrical and optical losses can be improved by introducing a dielectrically passivated and locally contacted rear side. To do so, the locally contacting rear side metallisation 108 can use a screen printed silver H-grid 108, as is the case on the front side of the cell.

To minimise the contact resistance between metallisation 108 and basis 106, it is necessary to dope intensively the surface at least in the region of metallisation 108 (so-called Back Surface Field). The doping process can be carried out in several variations. For example, the doping process can be performed as PERT (Passivated Emitter and Rear Totally diffused) or as PERL (Passivated Emitter and Rear Locally diffused).

With the PERT concept, the full surface of the solar cell rear side is doped (100%) while with the PERL concept only the region under metallisation 108 is doped (normally 5-20% of the whole surface).

Both concepts have advantages and shortcomings. The electrical conductivity of the BSF doping process improves in the PERT concept the lateral conductivity and thereby reduces ohmic losses. On the other hand, the high level of doping strengthens the recombination on the rear side so that recombination losses of the cell rise. This is the opposite with the PERL concept. As shown in FIGS. 3 and 4, the ohmic losses of a non-doped rear side are always higher than with PERT and cannot be completely compensated for by increased finger quantity.

A possible solution consists in lowering the BSF doping of the PERT concept until optimum compromise is found between recombination and transverse conductivity. The limitation is that for minimising the contact resistance of metallisation 108, a certain minimal concentration of doping agent must be present. Said concentration, in the case of metallisation pastes, is significantly greater than the quantity of doping agent which is necessary to obtain maximum efficiency.

The solution suggested consists in introducing different amounts of doping agents into regions 106, 110. The result is high concentration of doping agent under the metallisation 108 which enables the contacting process. There can be a medium concentration of doping agent between the fingers of the metallisation 108.

In this application, the region 106 between the fingers is highly doped and protrudes significantly over the metallised region, contrary to the PERL cell. A surface covering portion of 50% provides a conductivity which is similar to the PERT cell (100% covering). The reduced covering enables to lower the recombination on the rear side of the cell.

In a further exemplary embodiment, the region 110 between the highly doped areas 106 is slightly doped. This can improve for instance the long-term stability.

When laying out the cell 100, the surface covering portion F can range between 20% and 90%. Preferably, the surface covering portion F ranges between 40 and 60%. In the case of combination with an H grid, the finger quantity n can range between 40 and 150. (The width of the highly doped areas 106 is then calculated for a 15.6 cm solar cell as Idop=r15.6/n). The space intervals between the fingers can be variable. Similarly, the structure 104 can be combined with a full-surface metallisation. Also, the structure 104 can be combined with a rear side emitter cell. In such a case, a partially doped FSF is used.

From an electrical viewpoint, the cell 100 can be a p or n-type substrate 102. The highly-doped area 106 can for instance be doped with boron or phosphorus/arsenic. In the highly doped area 106, layer resistances of 5 to 150 Ohm/square, i.e. resistance per surface area, preferably 20-60 Ohm can be achieved. The intermediate area 110 can be non-doped or the layer resistance can range between 80 and 500 Ohm/square.

When processing, the doping areas can be shaped in different ways. By way of example, ion implantation with a mask, full-surface doping process followed by local back-etching, application of a local diffusion mask and subsequent doping or application of local sources of doping agent such as doping glasses, can be carried out.

The illustration shows an embodiment in which the residual area 110 is hardly doped. In this case, the wafer 102 is highly-doped under the fingers 108. Therebetween, the wafer 102 is hardly doped. The width or the space interval between the doped areas 106 and the intermediate spaces 110 is optimised. Normally, they have the same width. Doped areas 106 and intermediate spaces 110 form a finger grid.

FIG. 3 shows a potential and current density distribution inside a solar cell segment 300 with a locally doped contact structure 302. The contact structure 302 consists here, contrary to the application described, of a doped area which only has the width of the conductor track 108. The wafer of the solar cells is non-doped between the conductor tracks. The potential density and the current density are extremely high in the region of the contact structure 302. The potential density and the current density decrease quickly as one moves away from the contact structure 302. From a certain distance from the conductor track 108, the potential density and the current density are below a representation threshold. The potential density and the current density are so high in the region of the contact structure 302 that an electrical resistance of the semiconductor material of the wafer can cause superheating of the material.

Ohmic losses take place first and foremost in the region of high current density (da P=J2*rho). Regions of high current density appear mostly around the metallisation 108. Said effect is designated as current crowding.

FIG. 4 shows a potential and current density distribution inside a solar cell segment 400 with an extensively doped contact structure 402. Contrary to the solution presented here, the contact structure 402 consists of a closed doped surface, on which is arranged the conductor track 108. The surface is doped with the density from one end to the other. The potential density and the current density are high in the region of the conductor track. In comparison to the contact structure in FIG. 3, the potential density and the current density decrease significantly more slowly. The region of the whole doped surface has a potential density and a current density.

The losses are only minimal in regions remote from the metallisation 108, (x>0.05). The equipotential lines have a flat angle with respect to the BSF. Consequently, a high doping quantity is not strictly necessary.

FIGS. 3 and 4 show a potential and current density distribution (arrows) inside a PERC/PERL and a PERT solar cell segment with 30 Ohm BSF. The rear side metallisation is at x=0 and x=0.0035 cm. An equipotential front side was assumed, for simplification purposes.

FIG. 5 shows a representation of a relation 500 between an internal series resistance of several solar cell types and a finger quantity of a contact structure of the solar cells. The relation 500 is shown in a diagram with the finger quantity in abscissae and the series resistance in ordinates. The series resistance sinks as the finger quantity increases, in all types of solar cells. It should be noted that solar cells of PERL type show a larger decrease in series resistance. The decrease is smaller with PERT-type solar cells. However, the series resistance of PERT cells with a 100 Ohm Back-Surface-Field already as low with 40 fingers as the series resistance of the PERL cells with 110 fingers. There again, with 40 Ohm Back-Surface-Field PERT cells, the resistance is smaller by 30 percent.

The figure illustrates an internal series resistance for PERL and PERT cells with various finger quantity. Only the transverse line resistance is shown. Ohmic losses in the metallisation are not taken into account. (Rabse=2.5 Ohm*cm, 160 pm cell density).

FIG. 6 shows a representation of a relation between an internal series resistance and a doped surface portion of a contact structure according to an exemplary embodiment of the present invention. To do so, two different exemplary embodiments 600, 602 are presented in a common diagram. The diagram shows in abscissae the surface portion between zero percent surface portion and 100 percent surface portion. The series resistance is indicated in Ohms in ordinates. The first exemplary embodiment 600 is a photovoltaic cell with non-doped intermediate spaces between highly doped bands. The first exemplary embodiment is represented by way of example in FIG. 1. The series resistance is, at five percent surface portion of the highly doped bands, approx. six times higher than a minimum calculated obtainable series resistance, at 100 percent surface portion of the highly doped area. The series resistance decreases rapidly in the first exemplary embodiment 600 as the doped surface portion increases and comes close asymptotically to the minimum valve without falling below the same. Already at 40 percent surface portion, the series resistance is only ten percent higher than the minimum value. The second exemplary embodiment 602 is a photovoltaic cell with hardly doped intermediate spaces, as represented by way of example on FIG. 2. Here, the series resistance decreases similarly as the surface portion of the highly doped area increases. However, at five percent surface portion, the series resistance is only 30 percent higher than the minimum value. The series resistance has already reached the minimum value at 50 percent surface portion.

We can see the internal series resistance of a solar cell according to the present application for different surface covering portions of the highly doped area (40 Ohms). In one case, the intermediate area in non-doped (red), in another, in a medium area (blue). Only the transverse line resistance is shown. Ohmic losses in the metallisation are not taken into account. The photovoltaic cell shows an equipotential front side. The resistance in the illuminated area (homogenous generation) is slightly higher. The representation is based on a Rbase of 2.5 Ohm*cm, 160 pm cell thickness, 90 fingers. Joe is assessed through weighting according to the surface portion. J_80 Ohm −90 fA. J_80 Ohm −150 fA. J_none −20.

FIG. 7 shows a representation of a relation between a recombination rate and a doped surface portion of a contact structure according to an exemplary embodiment of the present invention. As in FIG. 6, both different exemplary embodiments 600, 602 are presented in a common diagram. The diagram shows in abscissae the surface portion between zero percent surface portion and 100 percent surface portion. The recombination rate is plotted in ordinates. The recombination rate for both exemplary embodiments 600, 602 increases with the surface portion. At 100 percent surface portion, both examples of embodiment 600,602 show a recombination rate of 150. The first exemplary embodiment 600 exhibits at five percent surface portion a recombination rate of 25. The second exemplary embodiment 602 exhibits at five percent surface portion a recombination rate of 95.

Reconciling the information of FIGS. 6 and 7 enables to apply economically a surface portion between 20 percent and 90 percent for both exemplary embodiments 600, 602. The profitability is even greater with a surface portion between 40 percent and 60 percent.

FIG. 8 shows a flow chart of a process 800 for producing a contact structure of a photovoltaic cell according to an exemplary embodiment of the present invention. The process 800 shows a step 802 of the preparation, a step 804 of the doping and a step 806 of the contacting. Step 802 describes the preparation of a wafer for the photovoltaic cell. In step 804 of the doping process, a surface portion at least of a side of the wafer is doped with a doping material to obtain a doped region. The doped region is formed as doped tracks. The tracks are separated by intermediate spaces. In step 806 of the contacting process, the doped region is contacted to provide the contact structure. To do so, a conductor material is applied onto the tracks in such a way that the tracks protrude beyond the conductor material on both sides.

In an exemplary embodiment, in step 804 of doping a surface portion is doped between 20 percent and 90 percent. In so doing, a surface portion from 10 percent to 80 percent is non-doped. In particular, in step 804 of doping a surface portion is doped between 40 percent and 60 percent. In so doing, a surface portion from 40 percent to 60 percent is non-doped. These surface portions enable to obtain optimum conductivity and minimum recombination.

In an exemplary embodiment, in step 804 of the doping process, the doped region is formed as at least one main track with a plurality of side tracks. To do so, the side tracks are finger-shaped and arranged transversally to the main track. Several main tracks with their side tracks can be distributed on the photovoltaic cell.

In an exemplary embodiment, the side tracks are arranged alternately to the main track.

In an exemplary embodiment, the side tracks are arranged alternately to the main track. The main and side tracks exhibit an H-shaped pattern whereby the main track represents the cross dash. A plurality of side tracks can be arranged on a main track.

In an exemplary embodiment, in step 804 of the doping process another doping material is applied to obtain a further doped region. The further doping material is separate from the doping material and the further doped region is formed as additional doped regions. The additional tracks are also separated from the tracks by intermediate spaces. The additional doped region is arranged on the same side as the doped region. A side opposite to this side is here non-doped or slightly doped and non-contacted.

In an exemplary embodiment, in step 804 of the doping process, the tracks are doped with a concentration of doping agent so that there is a specific resistance between 10 Ohm/m and 150 Ohm/m in the doped region. In an exemplary embodiment, in step 804 of the doping process, the tracks are doped with a concentration of doping agent so that there is a specific resistance between 20 Ohm/m and 60 Ohm/m in the doped region.

In an exemplary embodiment, in doping step 804 the intermediate spaces are doped with a smaller concentration of the doping material than the tracks. Thereby, the intermediate spaces are hardly doped. The slight doping reduces the electrical resistance in the intermediate space and thereby the electrical losses.

In an exemplary embodiment, in step 804 of the doping process, the intermediate spaces are doped with a concentration of doping agent so that there is a specific resistance between 80 Ohm/m and 500 Ohm/m in the intermediate spaces.

In an exemplary embodiment, during the doping step 804 the doping material is introduced in a first pass in the region of the tracks and of the intermediate spaces, to obtain the concentration of the doping material of the intermediate spaces. The doping material is introduced in a second pass in the region of the tracks, to obtain the concentration of the doping material in the doped region. There is a single doping process, instead of varying the doping intensity. The implantation is double in the case of a higher doping.

In an exemplary embodiment, during the doping step 804 a width of the tracks and/or a width of the intermediate spaces is determined on the basis of the processing requirement.

In an exemplary embodiment an ion implantation process is used during the doping step 804.

The application presented here results in improved cell efficiency by reducing the efficient rear side recombination. It is solely necessary to control a doping level. This simplifies the process with respect to a “classic” selective doping process, as used for selective emitters. The process presented here 800 can be combined with methods for avoiding edge shunts, such as edge mask. The requirements set to the alignment of metallisation are quite flexible since the metallisation need not be oriented with precision to highly-doped regions. The result is simplified implementation in the ion implanter with respect to a two-stage doping process. No mobile masks are necessary.

The examples of embodiment described and shown in the figures have been selected purely by way of example. Different examples of embodiment can be combined with each other completely or with reference to individual features. An example of embodiment can be completed with features of another example of embodiment.

Moreover, process steps according to the invention can be repeated as well as carried out in a sequence different from the one described.

If an example of embodiment contains an “and/or” connection between a first feature and a second feature, it should be understood that the exemplary embodiment according to a form of embodiment exhibits the first feature as well as the second feature and according to another form of embodiment either only the first feature or only the second feature.

1. A method (800) for producing a contact structure (104) of a photovoltaic cell (100), whereas the method (800) comprises the following steps:
providing (802) a wafer (102) for the photovoltaic cell (100);
doping (804) a surface portion of at least one side of the wafer (102) with a doping material to obtain a doped region (106), whereas the doped region (106) is formed as doped tracks (106) and the tracks (106) are separated by intermediate spaces (110); and
contacting (806) the doped region (106) to produce the contact structure (104), whereas a conductor material (108) is applied to the tracks (106) in such a way that the tracks (106) protrude beyond the conductor material (108) on both sides.

2. The method (800) according to claim 1, wherein during the step (804) of doping a surface portion is doped between 20 percent and 90 percent, in particular between 40 percent and 60 percent of at least one side of the wafer (102).

3. The method (800) according to claim 1, wherein during the doping step (804) the rear side is doped to produce the contact structure (104) on the rear side of the photovoltaic cell (100).

4. The method (800) according to claim 1, wherein during the doping step (804) the doped region (106) is formed as at least one main track with a plurality of side tracks, whereby the side tracks are finger-shaped and arranged transversally to the main track.

5. The method (800) according to claim 1, wherein during the doping step (804) a further doping material is introduced to obtain one more doped region whereas the additional doping material is different from the doping material and the additional doped region is formed as additional doped tracks and the additional tracks are separated by intermediate spaces (110) from the tracks (106).

6. The method (800) according to claim 1, wherein during the doping step (804) the tracks (106) are doped with a concentration of doping agent so that a layer resistance is adjusted between 5 /square and 150 /square, in particular between 20 /square and 60 /square in the doped region (106).

7. The method (800) according to claim 1, wherein during the doping step (804) the intermediate spaces (110) are doped with a smaller concentration of the doping material than the tracks (106).The method (800) according to claim 7, wherein during the doping step (804) the intermediate spaces (110) are doped with a concentration of doping agent to have a layer resistance between 80 /square and 500 /square in the intermediate spaces.

8. A method (800) according to claim 7, wherein during the doping step (804) the doping material is introduced in a first pass in the region of the tracks (106) and the intermediate spaces (110) to obtain the concentration of the doping material of the intermediate spaces (110) and the doping material is introduced in a second pass in the region of the tracks (106), to obtain the concentration of the doping material in the doped region (106).

9. The method (800) according to claim 1, wherein during the doping step (804) a width of the tracks (106) and/or a width of the intermediate spaces (110) is determined on the basis of the processing requirement.

10. The method (800) according to claim 1, wherein during the doping step (804) an ion implantation process is used.

11. The method (800) according to claim 1, wherein the doped region (106) and the intermediate spaces (110) are formed with phosphorus and are applied on the rear side of the photovoltaic cell (100) with n-type basis and boron-doped emitter.

12. A photovoltaic cell (100) with a wafer (102), exhibiting a contact structure (104) on at least one side, a structure composed of doped tracks (106) and of an applied conductor material (108), wherein the tracks (106) protrude beyond the conductor material (108) on both sides and the tracks (106) are separated by intermediate spaces (110).
